(19) United States
(12) Patent Application Publication
(10) Pub. No.: US 2026/0164980 A1
(43) Pub. Date: Jun. 11, 2026

(54) DISPLAY DEVICE

(71) Applicant: LG Display Co., Ltd., Seoul (KR)

(72) Inventor: Hoonsok SON, Paju-si (KR)

(73) Assignee: LG Display Co., Ltd., Seoul (KR)

(21) Appl. No.: 19/178,551

(22) Filed: Apr. 14, 2025

(30) Foreign Application Priority Data
Jul. 2, 2024 (KR) 10-2024-0086518

(51) Int. Cl. H10K 59/50; G02F 1/13357; H10K 59/00

(52) U.S. Cl. CPC H10K 59/50; G02F 1/133603; H10K 59/771

(57) ABSTRACT

A display device can include a first sub-pixel, a second sub-pixel, and a transparent area between the first and second sub-pixels. The display device can further include a substrate disposed across the first and second sub-pixels, an anode electrode disposed on the substrate for each sub-pixel, a common light-emitting layer disposed on each of the anode electrodes of the first and second sub-pixels, and a light control unit in the transparent area. The light control unit includes a lower electrode, an upper electrode opposing the lower electrode, and a liquid crystal layer between the lower and upper electrodes.

### CROSS-REFERENCE TO RELATED APPLICATION

The present application claims priority to Korean Patent Application No. 10-2024-0086518, filed in the Republic of Korea on Jul. 2, 2024, the entire contents of which are hereby expressly incorporated by reference into the present application.

### BACKGROUND OF THE DISCLOSURE

### Technical Field

This disclosure relates to a display device.

### Discussion of the Related Art

With the advancement of the information society, there is an increasing demand for display devices that can show images, Various types of display devices such as liquid crystal display (LCD) devices and organic light emitting diode (OLED) displays are being utilized.

Among such display devices, OLED displays are self-emissive, offering superior viewing angles and contrast ratios compared to LCDs, while eliminating the need for a separate backlight, enabling a lightweight and slim design with advantageous power consumption. Furthermore, OLED displays support low-voltage DC operations, feature fast response times, and, most notably, offer the advantage of lower manufacturing costs.

Recently, there has been a growing demand for OLED displays that cater to the requirements of augmented reality (AR), virtual reality (VR), and ultra-high-resolution display devices of comparable quality.

### SUMMARY OF THE DISCLOSURE

It is an object of this disclosure to provide a display device capable of selectively controlling a virtual reality (VR) mode and an augmented reality (AR) mode.

It is another object of this disclosure to provide a display device capable of switching between VR and AR modes by forming transparent areas between sub-pixels and placing an optical control member over these transparent areas.

It is still another object of this disclosure to provide a display device capable of selectively blocking or transmitting external light from below by means of an optical control member, which includes liquid crystal, an upper electrode on the liquid crystal, and a lower electrode beneath it, allowing the liquid crystal to be driven by the upper and lower electrodes.

The objects of this disclosure are not limited to those mentioned above, and other technical objects can be inferred from the following embodiments of this disclosure.

In order to accomplish the above objects, a display device according to an embodiment of this disclosure, includes a first sub-pixel, a second sub-pixel, and a transparent area between the first and second sub-pixels, a substrate disposed across the first and second sub-pixels, an anode electrode disposed on the substrate for each sub-pixel, a common light-emitting layer disposed on each of the anode electrodes of the first and second sub-pixels, and a light control unit in the transparent area, the light control unit comprising a lower electrode, an upper electrode opposing the lower electrode, and a liquid crystal layer between the lower and upper electrodes.

In order to accomplish the above objects, a display device according to an embodiment of this disclosure includes a first sub-pixel, a second sub-pixel, and a transparent area between the first and second sub-pixels, a substrate disposed across the first and second sub-pixels, an anode electrode disposed on the substrate within each sub-pixel, a common light-emitting layer disposed on each of the anode electrodes of the first and second sub-pixels, and a light control unit in the transparent area, the light control unit being configured to block light incident from outside the display device in a first mode, and to transmit light incident from outside the display device in a second mode.

The specific details of other embodiments are included in the detailed description and drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to one or more embodiments of this disclosure;

FIG. 2 is a cross-sectional view taken along line A-A′ of FIG. 1;

FIG. 3 is a cross-sectional view taken along line B-B′ of FIG. 1;

FIG. 4 is an enlarged cross-sectional view of the organic light-emitting device in FIG. 2;

FIG. 5 is an enlarged cross-sectional view of the organic light-emitting device in FIG. 2 as an alternative;

FIG. 6 is a schematic view of the VR mode of a display device according to an embodiment of this disclosure;

FIG. 7 is a schematic view of the AR mode of a display device according to an embodiment of this disclosure;

FIG. 8 is a cross-sectional view of a display device according to another embodiment of this disclosure;

FIG. 9 is a cross-sectional view of a display device according to another embodiment of this disclosure;

FIG. 10 is a cross-sectional view of a display device according to another embodiment of this disclosure;

FIG. 11 is a cross-sectional view of a display device according to another embodiment of this disclosure; and

FIG. 12 is a cross-sectional view of a display device according to another embodiment of this disclosure.

### DETAILED DESCRIPTION OF THE EMBODIMENTS

Hereinafter, various embodiments of this disclosure are described with reference to accompanying drawings. In the specification, when a component (or area, layer, part, etc.) is mentioned as being “on top of,” “connected to,” or “coupled to” another component, it means that it can be directly connected/coupled to the other component, or a third component (or additional components) can be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc. are used to describe various components, but the components should not be limited by these terms. The terms are used only for distinguishing one component from another component and may not define order or sequence. For example, a first component can be referred to as a second component and, similarly, the second component can be referred to as the first component, without departing from the scope of the embodiments. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof. Further, the term “can” fully encompasses all the meanings and coverages of the term “may” and vice versa.

Now, various embodiments of the present disclosure will be discussed. All the components of each display device according to all embodiments of the present disclosure are operatively coupled and configured.

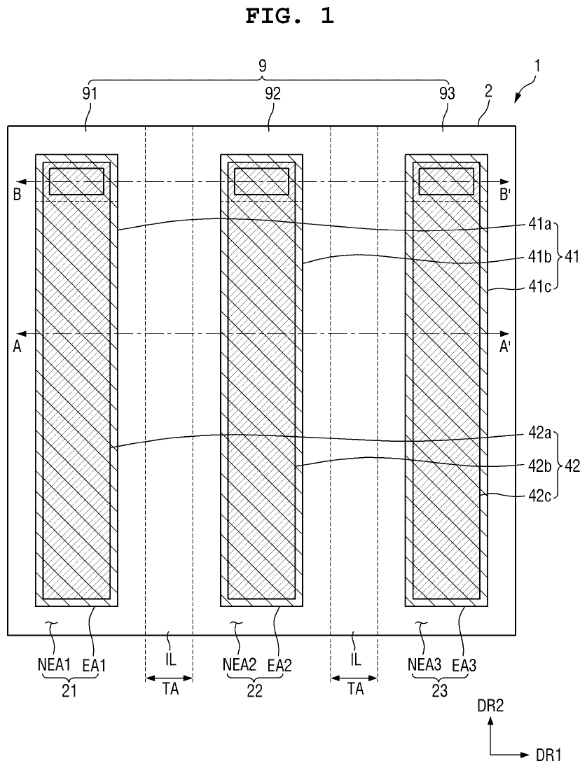

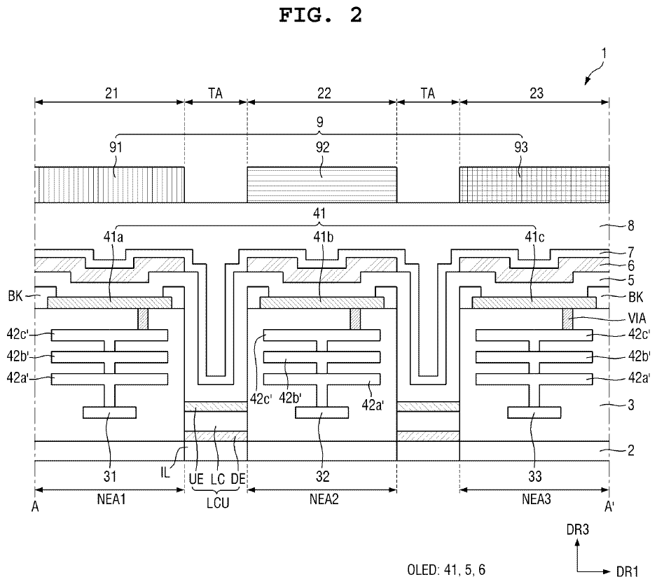

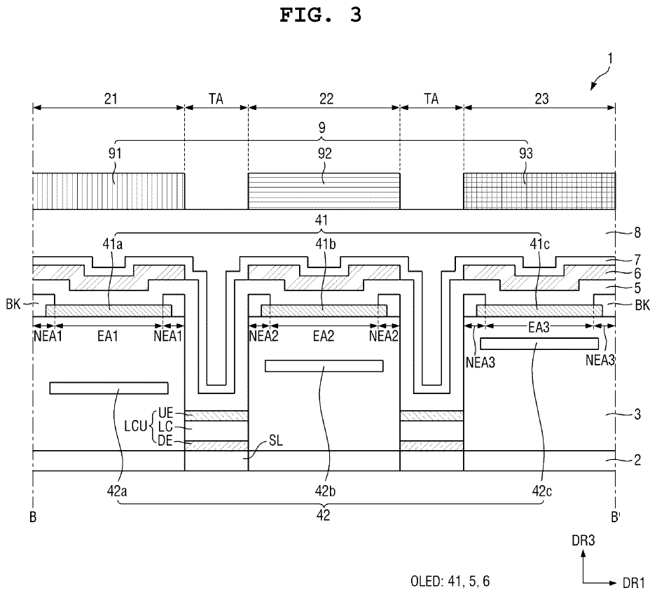

FIG. 1 is a plan view of a display device according to one or more embodiments of this disclosure. FIG. 2 is a cross-sectional view taken along line A-A′ of FIG. 1. FIG. 3 is a cross-sectional view taken along line B-B′ of FIG. 1.

Referring to FIGS. 1 to 3, a display device 1 according to some embodiments of this disclosure includes a substrate 2, an anode electrode 41, a common light-emitting layer 5, and a cathode electrode 6.

A plurality of sub-pixels 21, 22, and 23 are formed on the substrate 2. The plurality of sub-pixels 21, 22, and 23 can form a single pixel. A plurality of pixels can be formed on the substrate 2. The substrate 2 may not be disposed on the transparent area TA. A support part IL in contact with the substrate of adjacent sub-pixels 21, 22, and 23 can be disposed on the transparent area TA.

A transparent area TA can be formed between the first sub-pixel 21 and the second sub-pixel 22, and between the second sub-pixel 22 and the third sub-pixel 23.

The plurality of sub-pixels 21, 22, and 23 includes the first sub-pixel 21, the second sub-pixel 22, and the third sub-pixel 23. By arranging the first sub-pixel 21, the second sub-pixel 22, and the third sub-pixel 23 in order, the second sub-pixel 22 can be adjacent to one side of the first sub-pixel 21, for example, on the left, and the third sub-pixel 23 can be adjacent to one side of the second sub-pixel 22, for example, on the left.

Throughout this disclosure, the phrase “two sub-pixels are arranged adjacent to each other” should be interpreted to mean that no other sub-pixel is placed between the two sub-pixels.

The first sub-pixel 21 can be configured to emit red (R) light, the second sub-pixel 22 can be configured to emit green (G) light, and the third sub-pixel 23 can be configured to emit blue (B) light, although this is not necessarily limited to these colors.

In FIG. 1, the pixel is shown as including only three sub-pixels 21, 22, and 23, but it is not limited to this configuration, and the pixel can include four sub-pixels. When the pixel includes four sub-pixels, a fourth sub-pixel configured to emit white (W) light can be further included.

The first to third sub-pixels 21, 22, and 23 can each be configured with the same size. For example, the first to third sub-pixels 21, 22, and 23 can each be configured to have the same width and height. Here, the width can refer to the horizontal direction (first direction DR1) based on FIG. 1, and the height can refer to the direction perpendicular to the width (second direction DR2) based on FIG. 1, though the embodiments of this disclosure are not limited thereto.

Each sub-pixel 21, 22, and 23 can include a light-emitting area (EA1, EA2, EA3) and a non-light-emitting area (NEA1, NEA2, NEA3). The first sub-pixel 21 can include a first light-emitting area EA1 and a first non-light-emitting area NEA1 surrounding the first light-emitting area EA1, the second sub-pixel 22 can include a second light-emitting area EA2 and a second non-light-emitting area NEA2 surrounding the second light-emitting area EA2, and the third sub-pixel 23 can include a third light-emitting area EA3 and a third non-light-emitting area NEA3 surrounding the third light-emitting area EA3. Each light-emitting area (EA1, EA2, EA3) can be the same as the area exposed from the bank BK of the first electrodes 4a, 4b, and 4c, which will be described later.

The anode electrode 41 is patterned for each individual sub-pixel 21, 22, and 23. For example, a first anode electrode 41a is formed in the first sub-pixel 21, a second anode electrode 41b is formed in the second sub-pixel 22, and a third anode electrode 41c is formed in the third sub-pixel 23. The anode electrode 41 can function as the positive electrode of the display device 1. A bank (BK) can be disposed on the anode electrode 41. The bank BK is configured to cover the edges of the anode electrodes 41 that are disposed in the first to third sub-pixels 21, 22, and 23, thereby allowing the first sub-pixel 21, second sub-pixel 22, and third sub-pixel 23 to be separated. The anode electrode 41 can be electrically connected to a reflective electrode 42 on each sub-pixel 21, 22, and 23, but the embodiments of this disclosure are not limited to this.

By including reflective electrodes 42 with varying surface heights, the display device 1 can further improve light extraction efficiency using micro-cavity characteristics.

The micro-cavity characteristic refers to the phenomenon where constructive interference occurs and light is amplified when the distance between the reflective electrode 42 and the cathode electrode 6 is an integer multiple of the half-wavelength (λ/2) of the light emitted from the sub-pixels 21, 22, and 23, and the reflection and re-reflection processes between the reflective electrode 42 and the cathode electrode 6 continue to amplify the light, thereby continuously enhancing the external light extraction efficiency.

The common light-emitting layer 5 can be configured to emit white light. For example, the common light-emitting layer 5 can be configured as a 2-stack structure including a blue light-emitting layer, a yellow-green light-emitting layer, and a charge generation layer, or as a 3-stack structure including a blue light-emitting layer, a green light-emitting layer, a red light-emitting layer, and a charge generation layer to emit white light, but is not limited to these configurations and can be provided with a plurality of layers exceeding three stacks as possible as it is capable of emitting white light.

The common light-emitting layer 5 can be formed as a common layer extending across the entire first to third sub-pixels 21, 22, and 23, but the embodiments of this disclosure are not limited to this. For example, the common light-emitting layer 5 can be disposed on a transparent area TA, separated on the transparent area TA, or not disposed on the transparent area TA at all.

The cathode electrode 6 is provided to form an electric field with the anode electrode 41 and can function as a cathode. The cathode electrode 6 is disposed on the upper surface of the common light-emitting layer 5, which is opposite to the lower surface of the common light-emitting layer 5 where the anode electrode 41 contacts, and can be positioned on the first to third sub-pixels 21, 22, and 23, respectively. The cathode electrode 6 may not be disposed on the transparent area TA.

In the case of a top emission configuration, the cathode electrode 6 can function as the second electrode, and in the case of a bottom light-emitting configuration, it can function as the first electrode, including a reflective material. In the case of a top emission configuration, the cathode electrode 6 can be formed as a semi-transparent electrode to enhance light extraction efficiency using micro-cavity characteristics. The display device utilizes micro-cavity characteristics in the top emission configuration to improve light extraction efficiency, which is why the cathode electrode 6 is formed as a semi-transparent electrode, as an example.

The color filter layer 9 is provided on each of the first to third sub-pixels 21, 22, and 23 to block predetermined colors from the light emitted by the common light-emitting layer 5 of each sub-pixel 21, 22, and 23. The color filter layer 9 may not be disposed on the transparent area TA. The first color filter 91 provided in the first sub-pixel 21 can be configured to block all colors except for red (R) light. In this case, the first color filter 91 can be a red color filter. The second color filter 92 provided in the second sub-pixel 22 can be configured to block all colors except for green (G) light. In this case, the second color filter 92 can be a green color filter. The third color filter 93 provided in the third sub-pixel 23 can be configured to block all colors except for blue (B) light. In this case, the third color filter 93 can be a blue color filter. However, the embodiments of this disclosure are not limited to this configuration.

The first to third color filters 91, 92, and 93 provided in each of the first to third sub-pixels 21, 22, and 23 can be configured to have the same size as the respective sub-pixels or can be scaled up or down by a certain ratio of the size of each sub-pixel.

Transistors 31, 32, and 33 can be disposed in the non-light-emitting areas NEA1, NEA2, and NEA3 of each sub-pixel 21, 22, and 23. For example, transistors 31, 32, and 33 can overlap with the reflective electrodes 42a, 42b, and 42c disposed in each sub-pixel 21, 22, and 23. Transistors 31, 32, and 33 can be electrically connected to the reflective electrodes 42a, 42b, and 42c.

Hereinafter, a detailed description of the laminated structure of the display device 1 according to some embodiments of this disclosure is provided.

The display device 1 according to one or more embodiments of this disclosure includes sub-pixels 21, 22, and 23, as well as a transparent area TA between the sub-pixels 21, 22, and 23. The sub-pixels 21, 22, and 23 include a substrate 2, an insulating layer 3, an anode electrode 41, a bank BK, a common light-emitting layer 5, a cathode electrode 6, a capping layer 7, an encapsulation layer 8, and a color filter layer 9.

The substrate 2 can be made of a semiconductor material such as plastic film, glass substrate, or silicon.

The substrate 2 can be made of transparent or opaque materials. Sub-pixels 21, 22, and 23 are provided on the substrate 2. The first sub-pixel 21 can emit red (R) light, the second sub-pixel 22 can emit blue (B) light, and the third sub-pixel 23 can emit green (G) light. The substrate 2 may not be disposed on the transparent area TA.

In some embodiments of this disclosure, the display device 1 is configured in a so-called top emission method where the emitted light is released upwards, and therefore, the material of the substrate 100 can be either a transparent material or an opaque material. On the upper side of the first to third sub-pixels 21, 22, and 23), color filters 91, 92, and 93 can be provided to transmit light of the respective colors as mentioned above. In the transparent area TA, external light entering from the lower part of the light control unit LCU can either be blocked or transmitted. Therefore, a support part IL with a higher light transmittance than the substrate 2 can be disposed on the transparent area TA. The support part IL can include an organic insulating material or an inorganic insulating material, but the embodiments in this disclosure are not limited to these.

The insulating layer 3 is formed on the substrate 2. The insulating layer 3 can include an inorganic insulating material. The insulating layer 3 can be disposed on each of the sub-pixels 21, 22, and 23, but may not be disposed in the transparent area TA.

The insulating layer 3 includes circuit elements such as multiple thin-film transistors 31, 32, and 33, various signal lines, and capacitors, provided for each sub-pixel 21, 22, and 23. The signal lines can include gate lines, data lines, power lines, and reference lines, and the thin-film transistors 31, 32, and 33 can include switching thin-film transistors, driving thin-film transistors, and sensing thin-film transistors. Each of the sub-pixels 21, 22, and 23 is defined by the intersection structure of the gate lines and data lines. The insulating layer 3 can surround the thin-film transistors 31, 32, and 33.

The switching thin-film transistor switches according to the gate signal supplied to the gate line to supply the data voltage from the data line to the driving thin-film transistor.

The driving thin-film transistor switches according to the data voltage supplied from the switching thin-film transistor, generating data current from the power supplied through the power line, which is then supplied to the anode electrode 41.

The sensing thin-film transistor senses the threshold voltage variation of the driving thin-film transistor, which causes image quality degradation, and in response to the sensing control signal supplied from the gate line or a separate sensing line, it supplies the current from the driving thin-film transistor to the reference line.

The capacitor serves to maintain the data voltage supplied to the driving thin-film transistor for one frame and is connected to the gate terminal and source terminal of the driving thin-film transistor, respectively.

The first thin-film transistor 31, second thin-film transistor 32, and third thin-film transistor 33 are disposed in the insulating layer 3 for each sub-pixel 21, 22, 23. The first thin-film transistor 31 is connected to the first anode electrode 41a disposed on the first sub-pixel 21, thereby applying a driving voltage to emit light of the corresponding color for the first sub-pixel 21. The first thin-film transistor 31, second thin-film transistor 32, and third thin-film transistor 33 can be located in the same thin-film transistor layer, but the embodiments in this disclosure are not limited to this.

The second thin-film transistor 32 is connected to the second anode electrode 41b disposed on the second sub-pixel 22, thereby applying a driving voltage to emit light of the corresponding color for the second sub-pixel 22.

The third thin-film transistor 33 is connected to the third anode electrode 41c disposed on the third sub-pixel 23, thereby applying a driving voltage to emit light of the corresponding color for the third sub-pixel 23.

The first sub-pixel 21, second sub-pixel 22, and third sub-pixel 23 each supply a predetermined current to the light-emitting layer according to the data voltage of the data line when a gate signal is input from the gate line, using their respective transistors 31, 32, and 33. As a result, the light-emitting layers of the first sub-pixel 21, second sub-pixel 22, and third sub-pixel 23 can emit light at a predetermined brightness according to the supplied current.

The insulating layer 3 can protect the transistors 31, 32, and 33. The insulating layer 3 can be made of an inorganic insulating material, but it is not limited to this, and can also be made of an organic insulating material. For example, the insulating layer 3 can be made of an inorganic insulating material such as silicon nitride (SiNx), silicon oxide (SiOx), or aluminum oxide (Al₂O₃), but the embodiments in this disclosure are not limited to these materials.

The insulating layer 3 is not disposed in the transparent area TA, and in the transparent area TA, a light control unit LCU can be disposed on the support part IL. The surface height of the light control unit LCU can be lower than the surface height of the insulating layer 3.

The insulating layer 3 can have a via hole VIA formed on its upper surface, which is electrically connected to the anode electrodes 41a, 41b, and 41c. The via hole VIA can penetrate the insulating layer 3 in the thickness direction and be electrically connected to the reflective electrodes 42a, 42b, and 42c of each sub-pixel 21, 22, and 23. The via hole VIA can contain metal. For example, the via hole VIA can include tungsten, but the embodiments in this disclosure are not limited to this. The via hole VIA can be disposed in the non-light-emitting areas NEA1, NEA2, and NEA3.

The reflective electrode layer can be disposed on the insulating layer 3. The reflective electrode layer can include the reflective electrode 42. The reflective electrode 42 can include the first reflective electrode 42a of the first sub-pixel 21, the second reflective electrode 42b of the second sub-pixel 22, and the third reflective electrode 42c of the third sub-pixel 23. The reflective electrodes 42a, 42b, and 42c can be disposed in the light-emitting areas EA1, EA2, and EA3, respectively, and can extend to some non-light-emitting areas NEA1, NEA2, and NEA3. For example, as shown in FIG. 3, the distance between the first reflective electrode 42a and the cathode electrode 6 can be greater than the distance between the second reflective electrode 42b and the cathode electrode 6, and the distance between the second reflective electrode 42b and the cathode electrode 6 can be greater than the distance between the third reflective electrode 42c and the cathode electrode 6.

The reflective electrodes 42a, 42b, and 42c can reflect light emitted from the common light-emitting layer 5 of each sub-pixel 21, 22, and 23 back toward the cathode electrode 6 or encapsulation layer 8. Additionally, the reflective electrode 42 is intended to implement micro-cavity characteristics through reflection and re-reflection with the cathode electrode 6. To achieve this, the reflective electrode 42 can include a reflective material for reflecting light. For example, the reflective material can be metal, but it is not limited to this, and any other material capable of reflecting light can also be used. For example, the reflective material can include aluminum (Al) or silver (Ag), but the embodiments in this disclosure are not limited to these. The reflective electrode 42 is disposed at a relatively lower position than the common light-emitting layer 5, allowing reflection of the light emitted from the common light-emitting layer 5 upwards. Here, the upward direction refers to the direction in which the user perceives the light, which may, for example, be the side where the encapsulation layer 8 or the color filter layer 9 is disposed. As a result, the first sub-pixel 21, second sub-pixel 22, and third sub-pixel 23 can achieve higher light efficiency compared to when the reflective electrode 42 is not present, and the user can perceive a high luminance, i.e., a sharper image, through the improved light efficiency.

The reflective electrodes 42a, 42b, and 42c are formed at varying distances (or resonant distances) from the cathode electrode 6 in order to improve the light extraction efficiency for different colors of light through reflection and re-reflection between the reflective electrodes 42a, 42b, and 42c and the cathode electrode 6. Therefore, in the first sub-pixel 21, the light extraction efficiency for red light can be enhanced, in the second sub-pixel 22, the light extraction efficiency for green light can be enhanced, and in the third sub-pixel 23, the light extraction efficiency for blue light can be enhanced.

As shown in FIG. 2, the non-light-emitting areas NEA1, NEA2, and NEA3 can have the first reflective pattern 42a′, second reflective pattern 42b′, and third reflective pattern 42c′ disposed therein.

The first reflective pattern 42a′ can be disposed in the same layer as the first reflective electrode 42a (see FIG. 3) and can include the same material. The first reflective pattern 42a′ can be physically separated from the first reflective electrode 42a.

The second reflective pattern 42b′ can be disposed in the same layer as the second reflective electrode 42b (see FIG. 3) and can include the same material. The second reflective pattern 42b′ can be physically separated from the second reflective electrode 42b.

The third reflective pattern 42c′ can be disposed in the same layer as the third reflective electrode 42c (see FIG. 3) and can include the same material. The third reflective pattern 42c′ can be physically separated from the third reflective electrode 42c.

In the first non-light-emitting area NEA1, the first reflective electrode 42a is electrically connected to the first thin-film transistor 31, and the second reflective pattern 42b′ and the third reflective pattern 42c′ can be sequentially disposed on the first reflective electrode 42a. The third reflective pattern 42c′ is electrically connected to the second reflective pattern 42b′, and the second reflective pattern 42b′ can be electrically connected to the first reflective electrode 42a. The first anode electrode 41a can be electrically connected to the third reflective pattern 42c′ through a via hole VIA.

In the second non-light-emitting area NEA2, the first reflective pattern 42a′ is electrically connected to the second thin-film transistor 32, and the second reflective electrode 42b and the third reflective pattern 42c′ can be sequentially disposed on the first reflective pattern 42a′. The third reflective pattern 42c′ is electrically connected to the second reflective electrode 42b, and the second reflective electrode 42b can be electrically connected to the first reflective pattern 42a′. The second anode electrode 41b can be electrically connected to the third reflective pattern 42c′ through a via hole VIA.

In the third non-light-emitting area NEA3, the first reflective pattern 42a′ is electrically connected to the third thin-film transistor 33, and the second reflective pattern 42b′ and the third reflective electrode 42c can be sequentially disposed on the first reflective pattern 42a′. The third reflective electrode 42c is electrically connected to the second reflective pattern 42b′, and the second reflective pattern 42b′ can be electrically connected to the first reflective pattern 42a′. The third anode electrode 41c can be electrically connected to the third reflective pattern 42c′ through a via hole VIA.

The anode electrodes 41 are patterned for each of the first to third sub-pixels 21, 22, and 23. The anode electrodes 41 are connected to the driving thin-film transistors provided in the insulating layer 3. For example, the anode electrodes 41 can be electrically connected to the transistors 31, 32, and 33 through the aforementioned via holes VIA, reflective electrodes, and reflective patterns.

The anode electrodes 41a, 41b, and 41c are disposed in the anode electrode layer, positioned in the same layer, and can include the same material.

For example, the anode electrodes 41a, 41b, and 41c can include transparent conductive materials. For example, the anode electrodes 41a, 41b, and 41c can include ITO, IZO, or TiN, but are not limited thereto.

The upper surfaces of each anode electrode 41a, 41b, and 41c can be positioned on the same line, but the embodiments in this disclosure are not limited to this.

The anode electrodes 41 of each sub-pixel 21, 22, and 23 can be physically separated from the anode electrodes 41 of adjacent sub-pixels 21, 22, and 23. A transparent area TA can be disposed in the space between the anode electrodes 41 of adjacent sub-pixels 21, 22, and 23.

A bank BK can be disposed on the anode electrodes 41a, 41b, and 41c. The bank BK can be made of inorganic insulating materials such as silicon nitride (SiNx), silicon oxide (SiOx), or aluminum oxide (Al₂O₃), but the embodiments in this disclosure are not limited to these materials. The bank BK can be disposed in the non-light-emitting areas NEA1, NEA2, and NEA3. The bank BK may not be disposed in the transparent area TA.

In the light-emitting areas EA1, EA2, and EA3, the bank BK can expose the upper surface of the anode electrodes 41a, 41b, and 41c to define the light-emitting areas EA1, EA2, and EA3.

The common light-emitting layer 5 is formed on the anode electrodes 41 and the bank BK. The common light-emitting layer 5 can be in contact with the upper surface of the anode electrode 41. The common light-emitting layer 5 can directly contact the upper and side surfaces of the anode electrodes 41a, 41b, and 41c, as well as the bank BK. The common light-emitting layer 5 can also extend and be disposed in the transparent area TA, but the embodiments in this disclosure are not limited to this.

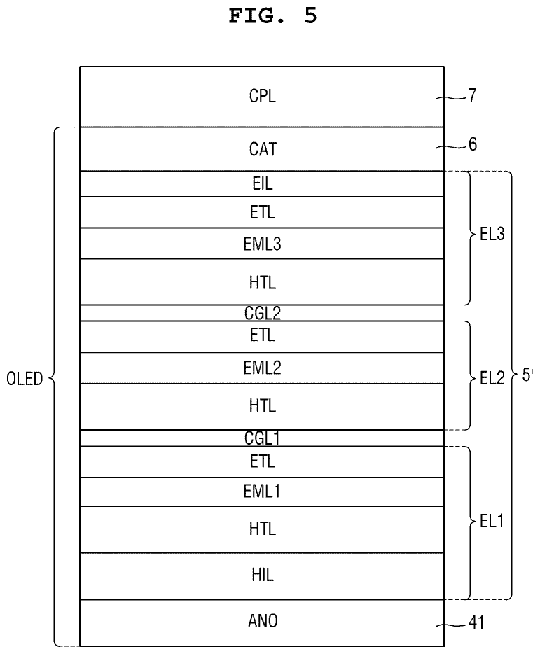

An organic light-emitting device OLED according to an embodiment of this disclosure can include the anode electrode 41 (ANO in FIG. 5), the cathode electrode 6 (CAT in FIG. 5), and the common light-emitting layer 5 between the anode electrode 41 and the cathode electrode 6.

The common light-emitting layer 5 can be configured to emit white (W) light. To achieve this, the common light-emitting layer 5 can include a plurality of stacks that emit light of different colors. Specifically, the common light-emitting layer 5 can include a first stack, a second stack, and a charge generation layer CGL disposed between the first stack and the second stack.

The cathode electrode 6 is formed on the common light-emitting layer 5. The cathode electrode 6 can function as the cathode of the display device 1. The cathode electrode 6 can be disposed in each sub-pixel 21, 22, and 23, like the common light-emitting layer 5, but may not be disposed in the transparent area TA.

In some embodiments of this disclosure, the display device 1 can have a cathode electrode 6 made of a semi-transparent electrode to implement white light with high light efficiency in the top emission configuration. As a result, micro cavity effects can be obtained for each of the first to third sub-pixels 21, 22, and 23. The micro cavity effect can be achieved by repeated reflection and re-reflection of light between the cathode electrode 6 and the reflective electrode 42, which improves light extraction efficiency.

Meanwhile, since the cathode electrode 6 is formed on the upper surface of the common light-emitting layer 5, it can be shaped according to the profile of the common light-emitting layer 5. Since the common light-emitting layer 5 is formed following the profile of the anode electrode 41 in the light-emitting region, the cathode electrode 6 can ultimately be formed to follow the profile of the anode electrode 41. Additionally, the capping layer 7 on the cathode electrode 6 can also be formed to follow the profile of the cathode electrode 6.

The capping layer 7 can be made of an inorganic insulating material, but is not limited thereto. The capping layer 7 can be disposed on the cathode electrode 6 to protect the organic light-emitting device (OLED). The capping layer 7 can extend over the transparent area TA, but the embodiments in this disclosure are not limited to this, and it may not be disposed on the transparent area TA.

The encapsulation layer 8 is formed on the cathode electrode 6 to prevent external moisture from penetrating into the common light-emitting layer 5. This encapsulation layer 8 can be made of an inorganic insulating material or can be formed in an alternating stack structure of inorganic and organic insulating materials, but is not limited to these configurations. The encapsulation layer 8 can extend over the transparent area TA, but the embodiments in this disclosure are not limited to this, and it may not be disposed on the transparent area TA.

The color filter layer 9 is formed on the encapsulation layer 8. The color filter layer 9 can include a first color filter 91 of red (R) provided in the first sub-pixel 21, a second color filter 92 of green (G) provided in the second sub-pixel 22, and a third color filter 93 of blue (B) provided in the third sub-pixel 23, but is not limited to these configurations. The color filters 91, 92, and 93 may not be disposed over the transparent area TA.

The transparent area TA can have the aforementioned support part IL disposed thereon. The optical control part LCU can be disposed on the support part IL. The optical control part LCU can include a top electrode UE, a bottom electrode DE between the top electrode UE and the support part IL, and a liquid crystal layer LC between the top electrode UE and the bottom electrode DE. The liquid crystal layer LC can have a plurality of liquid crystal molecules sprayed and arranged thereon.

Although the surface of the support part IL is shown as being positioned on the same plane as the surface of the substrate 2 in FIGS. 2 and 3, this configuration is not limited thereto, and the surface of the support part IL can be higher or lower than the surface of the substrate 2.

The optical control part LCU can directly contact the adjacent insulating layer 3. For example, the top electrode UE, the liquid crystal layer LC, and the bottom electrode DE of the optical control part LCU can directly contact the insulating layer 3 of the adjacent sub-pixels 21, 22, and 23. However, the embodiments in this disclosure are not limited to this, and the top electrode UE, liquid crystal layer LC, and bottom electrode DE may not directly contact the insulating layer 3 of the adjacent sub-pixels 21, 22, and 23.

As shown in FIGS. 2 and 3, when the common light-emitting layer 5 is disposed in the transparent area TA, the common light-emitting layer 5 can directly contact the top electrode UE.

As mentioned above, the surface height of the optical control part LCU can be lower than the surface height of the insulating layer 3. Therefore, the common light-emitting layer 5 can directly contact the side surface of the insulating layer 3 in the transparent area TA. In other words, the common light-emitting layer 5 can directly contact the side surface of the insulating layer 3 and the top surface of the top electrode UE. The capping layer 7 can be disposed in the transparent area TA, following the profile of the common light-emitting layer 5.

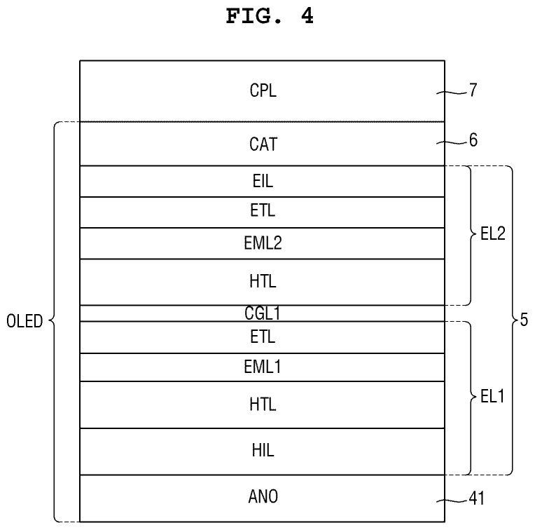

FIG. 4 is an enlarged cross-sectional view of the organic light-emitting device in FIG. 2. FIG. 5 is an enlarged cross-sectional view of the organic light-emitting device in FIG. 2 as an alternative.

Referring to FIGS. 1 to 4, the common light-emitting layer 5 can include a first stack EL1, a second stack EL2, and a first charge generation layer CGL1 formed on the anode electrode 41.

The first stack EL1 is provided on the anode electrode 41 and can have a structure where a hole injecting layer HIL, a hole transporting layer HTL, a blue (B) emitting layer EML1, and an electron transporting layer ETL are sequentially stacked.

The first stack EL1 can also be disposed in the transparent area TA, but the embodiments in this disclosure are not limited thereto.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a yellow-green (YG) emitting layer EML2, an electron transporting layer ETL, and an electron injecting layer EIL are sequentially stacked.

The second stack EL2 can also be disposed in the transparent area TA, but the embodiments in this disclosure are not limited thereto.

As shown in FIG. 2 and FIG. 3, the common light-emitting layer 5 can also be disposed in the transparent area TA, but the embodiments in this disclosure are not limited thereto.

As shown in FIG. 5, the common light-emitting layer 5′of the organic light-emitting device (OLED) according to an embodiment of this disclosure can include the first stack EL1, the second stack EL2, the third stack EL3, the first charge generation layer CGL1 between the first stack EL1 and the second stack EL2, and the second charge generation layer CGL2 between the second stack EL2 and the third stack EL3, provided on the anode electrode 41.

The first stack EL1 is provided on the anode electrode 41 and can have a structure where a hole injecting layer HIL, a hole transporting layer HTL, a blue (B) emitting layer EML1, and an electron transporting layer ETL are sequentially stacked.

The first stack EL1 can also be disposed in the transparent area TA, but the embodiments in this disclosure are not limited thereto.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a green (G) emitting layer EML2, and an electron transporting layer ETL are sequentially stacked.

The second stack EL2 can also be disposed in the transparent area TA, but the embodiments in this disclosure are not limited thereto.

The second charge generation layer CGL2 serves to supply charge to the second stack EL2 and the third stack EL3. The second charge generation layer CGL2 can include an N-type charge generation layer to supply electrons to the second stack EL2 and a P-type charge generation layer to supply holes to the third stack EL3. The N-type charge generation layer can be made by doping a metal material.

The third stack EL3 is provided on the second stack EL2 and can have a structure where a hole transporting layer HTL, a red (R) emitting layer EML3, an electron transporting layer ETL, and an electron injecting layer EIL are sequentially stacked.

As shown in FIGS. 1 to 5, the charge generation layers CGL1 and CGL2 can also be disposed in the transparent area TA. In the display device according to the embodiments, since the common light-emitting layer 5 (5′) is disposed between the sub-pixels 21, 22, and 23, side leakage current can occur through the charge generation layers CGL1 and CGL2 when one sub-pixel emits light. However, the transparent area TA disposed between the sub-pixels 21, 22, and 23, and the surface height of the LCU in the transparent area TA being lower than that of the insulating layer 3, increases the formation length of the common light-emitting layer 5 (5′) at the boundary of the sub-pixels 21, 22, and 23 or transparent area TA. This, in turn, lengthens the current path and prevents side leakage current. As a result, side leakage current can be prevented. Furthermore, by separating the common light-emitting layer 5 in the transparent area TA, side leakage current can be prevented in advance.

Referring again to FIGS. 2 and 3, the cathode electrode 6 is formed on the common light-emitting layer 5, the encapsulation layer 8 is formed on the cathode electrode 6, and the color filter layer 9 is formed on the encapsulation layer 8. The encapsulation layer 8 can be made of an inorganic insulating material or an organic insulating material and can be formed in a laminated structure of inorganic and organic materials. The encapsulation layer 8 can be a planarization layer, but the embodiments described in this disclosure are not limited to this. The thickness (t2) of the encapsulation layer 8 in the transparent area TA can be greater than the thickness (t1) of the encapsulation layer 8 in the sub-pixels 21, 22, and 23.

A black matrix for preventing color mixing between the first to third color filters 91, 92, and 93 can be provided between the sub-pixels, but the embodiments described in this disclosure are not limited to this.

A display device 1 according to an embodiment of this disclosure can be capable of switching between a first mode (e.g., VR Mode) and a second mode (e.g., AR Mode). The display device 1 can selectively control the first mode (VR Mode) and the second mode (AR Mode). Hereinafter, each mode will be described in detail.

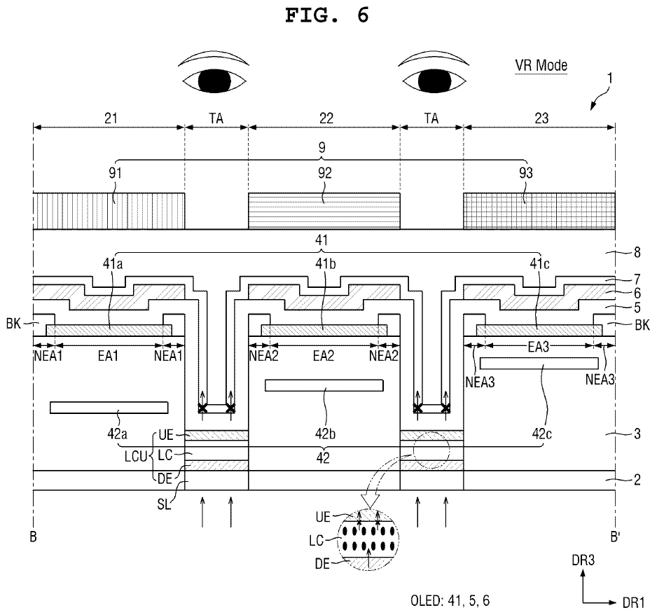

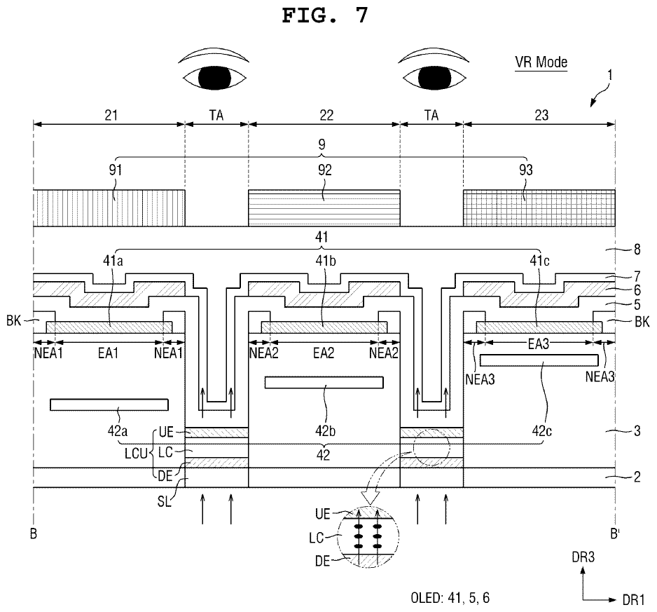

FIG. 6 is a schematic view of the VR mode of a display device according to an embodiment of this disclosure. FIG. 7 is a schematic view of the AR mode of a display device according to an embodiment of this disclosure.

Referring to FIGS. 6 and 7, first, in the first mode, a voltage may not be applied to the upper electrode UE and the lower electrode DE. Therefore, in the first mode, current may not flow from the upper electrode UE to the lower electrode DE or from the lower electrode DE to the upper electrode UE. As a result, the liquid crystal molecules in the liquid crystal layer LC can align in the thickness direction, as shown in FIG. 6. When the liquid crystal molecules align in the thickness direction, the liquid crystal layer LC becomes in a black state, blocking external light entering from below the support part IL.

In the first mode, each sub-pixel 21, 22, and 23 generates an image, while in the transparent area TA, external light is blocked, so the user can only see the images generated by the sub-pixels 21, 22, and 23, enabling the VR mode to be implemented.

Next, in the second mode, a voltage can be applied to the upper electrode UE and the lower electrode DE. For example, one of the upper electrode UE and the lower electrode DE can have a positive voltage applied, while the other one can have a negative voltage applied. Therefore, in the second mode, current can flow from the upper electrode UE to the lower electrode DE or from the lower electrode DE to the upper electrode UE. As a result, the liquid crystal molecules in the liquid crystal layer LC can align in the horizontal direction, as shown in FIG. 7. When the liquid crystal molecules align in the horizontal direction, the liquid crystal layer LC becomes in a white state, allowing external light to pass through from below the support part IL.

In the second mode, each sub-pixel 21, 22, and 23 generates an image, and at the same time, in the transparent area TA, external light passes through, so the user can see the images generated by the sub-pixels 21, 22, and 23 as well as the external light passing through the transparent area TA, enabling the AR mode to be implemented.

Hereinafter, descriptions of display devices according to other embodiments will be provided. In explaining the following embodiments, detailed descriptions of configurations that are the same as or similar to those described with reference to FIGS. 1 to 6 will be omitted to avoid redundancy or may be briefly provided.

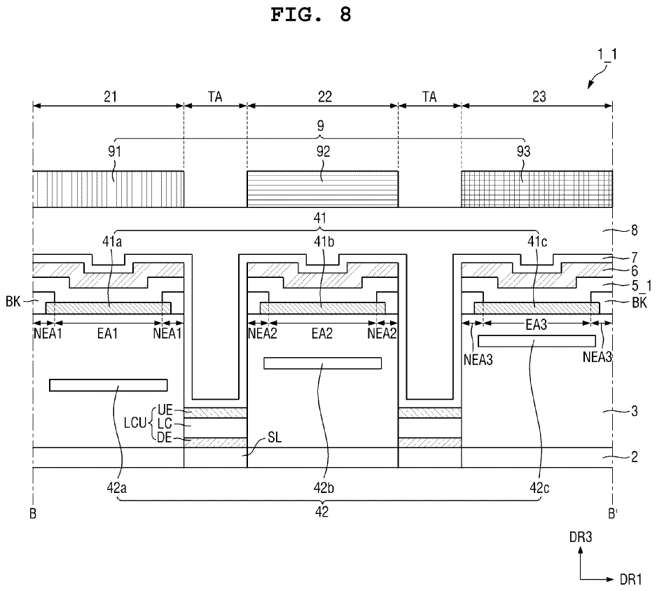

FIG. 8 is a cross-sectional view of a display device according to another embodiment of this disclosure.

The display device 1_1 according to the embodiment of FIG. 8 differs from the display device 1 according to the embodiment of FIG. 3 in that the common light-emitting layer 5_1 is not disposed in the transparent area TA.

Referring to FIG. 8, in more detail, the capping layer 7 can directly contact the side surface of the cathode electrode 6, the side surface of the common light-emitting layer 5_1, the side surface of the bank BK, the side surface of the insulating layer 3, and the top surface of the light control unit LCU.

By not disposing the common light-emitting layer 5_1 in the transparent area TA, side leakage currents between adjacent sub-pixels 21, 22, and 23 can be prevented in advance.

The additional description that has already been made with reference to FIG. 3 will be omitted.

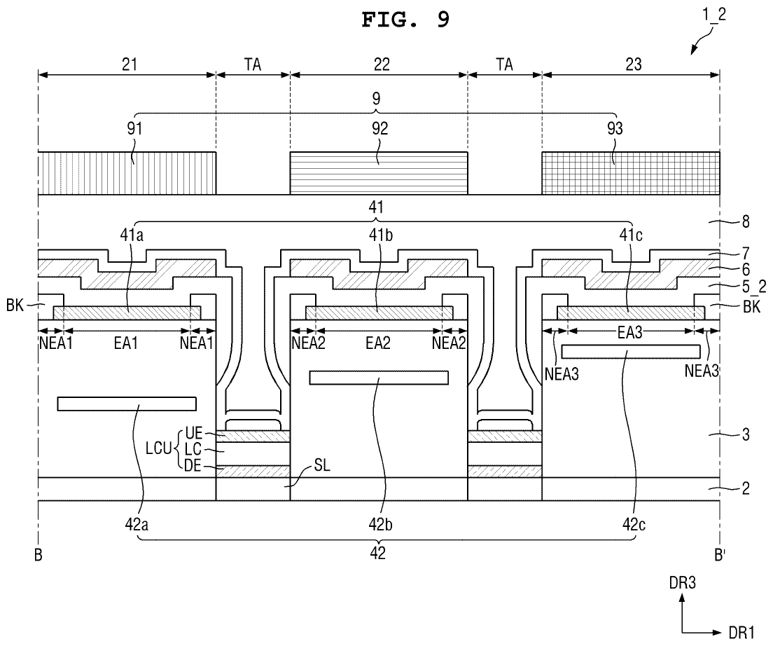

FIG. 9 is a cross-sectional view of a display device according to another embodiment of this disclosure.

The display device 1_2 according to the embodiment of FIG. 9 differs from the display device 1 according to the embodiment of FIG. 3 in that the common light-emitting layer 5_2 is physically separated in the transparent area TA.

Referring to FIG. 9, in more detail, the common light-emitting layer 5_2 is divided into a portion in contact with the side surface of the insulating layer 3 and a portion in contact with the upper surface of the light control unit LCU, and these two portions can be physically separated. The common light-emitting layer 5_2 can be in direct contact with the upper portion of the side surface of the insulating layer 3 that is not in contact with the light control unit LCU while exposing the lower portion. The capping layer 7 can be in direct contact with the lower portion of the insulating layer 3 exposed by the common light-emitting layer 5_2 without contacting the light control unit LCU.

By being physically separated in the transparent area TA, the common light-emitting layer 5_2 can prevent side leakage currents between adjacent sub-pixels 21, 22, and 23 in advance.

The additional description that has already been made with reference to FIG. 3 will be omitted.

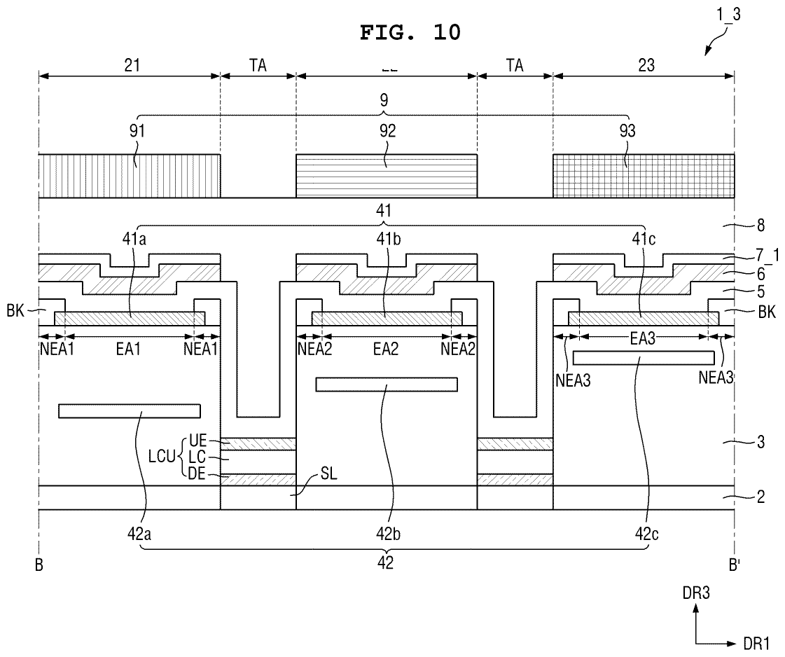

FIG. 10 is a cross-sectional view of a display device according to another embodiment of this disclosure.

The display device 1_3 according to the embodiment of FIG. 10 differs from the display device 1 according to the embodiment of FIG. 3 in that a capping layer 7_1 is included.

Referring to FIG. 10, in more detail, the capping layer 7_1 may not be disposed in the transparent area TA. Accordingly, the encapsulation layer 8 can be in direct contact with the side surface of the capping layer 7_1, the side surfaces of the anode electrodes 41a, 41b, and 41c, and the upper surface of the common light-emitting layer 5.

The additional description that has already been made with reference to FIG. 3 will be omitted.

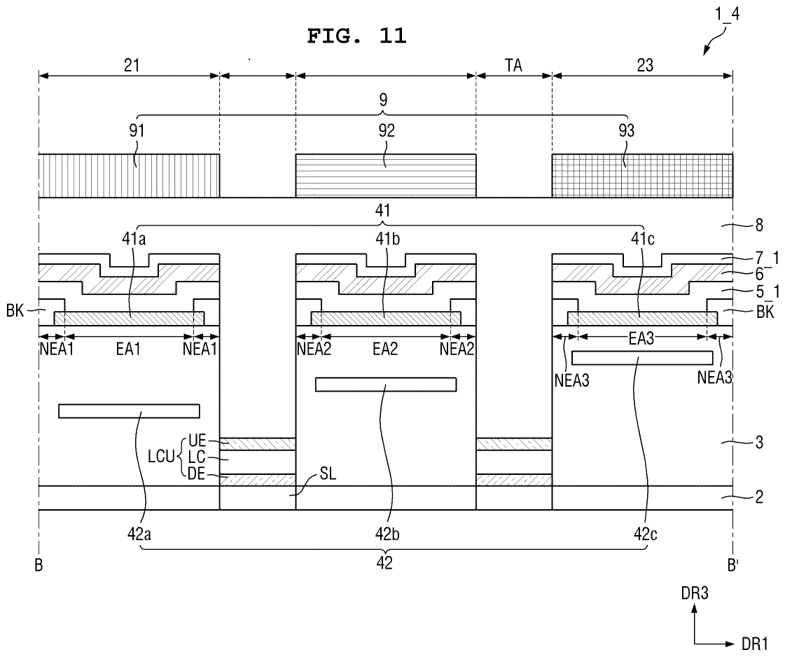

FIG. 11 is a cross-sectional view of a display device according to another embodiment of this disclosure.

The display device 1_4 according to the embodiment of FIG. 11 differs from the display device 1_1 according to the embodiment of FIG. 8 in that a capping layer 7_1 is included.

Referring to FIG. 11, in more detail, the capping layer 7_1 may not be disposed in the transparent area TA. Accordingly, the encapsulation layer 8 can directly contact the side surface of the capping layer 7_1, the side surfaces of the anode electrodes 41a, 41b, and 41c, and the side surface of the common light-emitting layer 5_1.

The additional description that has already been made with reference to FIG. 8 will be omitted.

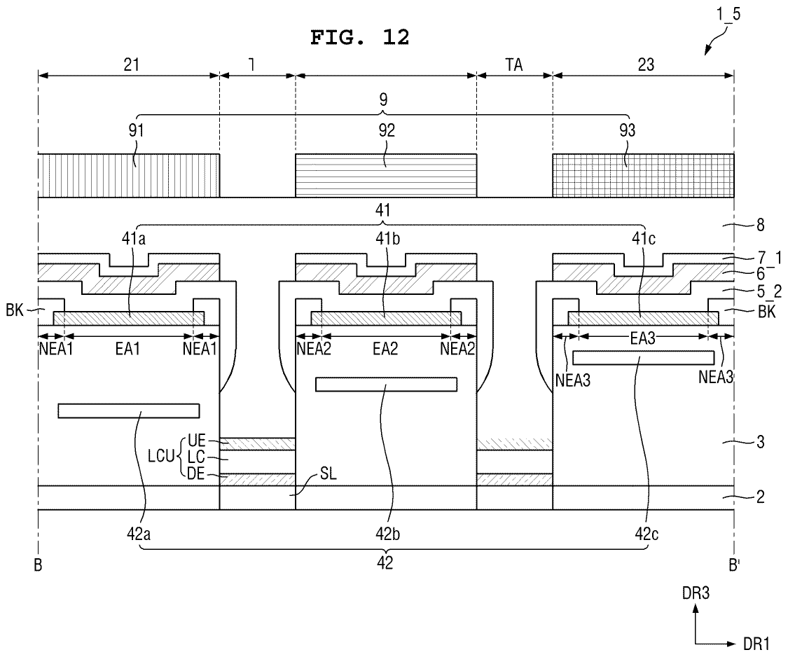

FIG. 12 is a cross-sectional view of a display device according to another embodiment of this disclosure.

The display device 1_5 according to the embodiment of FIG. 12 differs from the display device 1_2 according to the embodiment of FIG. 9 in that a capping layer 7_1 is included.

Referring to FIG. 12, in more detail, the capping layer 7_1 may not be disposed in the transparent area TA. Accordingly, the encapsulation layer 8 can directly contact the side surface of the capping layer 7_1, the side surface of each anode electrode 41a, 41b, and 41c, the top surface of the common light-emitting layer 5_1, and the side surface of the insulating layer 3 exposed by the common light-emitting layer 5_1. The encapsulation layer 8 can also contact the top surface of the light control unit LCU, but the embodiments described herein are not limited to this configuration.

The additional description that has already been made with reference to FIG. 9 will be omitted.

The display device according to various embodiments of this disclosure can be described as follows.

A display device according to various embodiments of this disclosure, which can be composed of a first sub-pixel, a second sub-pixel, and a transparent area between the first and second sub-pixels, includes a substrate disposed across the first and second sub-pixels, an anode electrode disposed on the substrate for each sub-pixel, a common light-emitting layer disposed on each of the anode electrodes of the first and second sub-pixels, and a light control unit in the transparent area, the light control unit including a lower electrode, an upper electrode opposing the lower electrode, and a liquid crystal layer between the lower and upper electrodes.

In the display device according to various embodiments of this disclosure, the substrate may not disposed in the transparent area.

The display device according to various embodiments of this disclosure can further include a support part supporting the light control unit in the transparent area.

In the display device according to various embodiments of this disclosure, the support part can have an optical transmittance higher than the optical transmittance of the substrate.

The display device according to various embodiments of this disclosure can further include a bank disposed between the anode electrode and the common light-emitting layer, covering an end of the anode electrode.

In the display device according to various embodiments of this disclosure, the bank may not disposed in the transparent area.

The display device according to various embodiments of this disclosure can further include an insulating layer between the anode electrode and the substrate, wherein the light control unit has a surface height thereof lower than the surface height of the insulating layer.

In the display device according to various embodiments of this disclosure, the common light-emitting layer may not disposed in the transparent area.

In the display device according to various embodiments of this disclosure, the common light-emitting layer can be separated from the transparent area.

The display device according to various embodiments of this disclosure further includes a cathode electrode on the common light-emitting layer, wherein the first sub-pixel can include a first reflective electrode within the insulating layer, the second sub-pixel can include a second reflective electrode within the insulating layer, and the distance between the first reflective electrode and the cathode electrode in the first sub-pixel can be greater than the distance between the second reflective electrode and the cathode electrode in the second sub-pixel.

In the display device according to various embodiments of this disclosure, the cathode electrode may not disposed in the transparent area.

The display device according to various embodiments of this disclosure further includes an encapsulation layer on the cathode electrode, wherein the thickness of the encapsulation layer in the transparent area can be greater than the thickness of the encapsulation layer in the first sub-pixel.

A display device according to various embodiments of this disclosure, which can be composed of a first sub-pixel, a second sub-pixel, and a transparent area between the first and second sub-pixels, includes a substrate disposed across the first and second sub-pixels, an anode electrode disposed on the substrate within each sub-pixel, a common light-emitting layer disposed on each of the anode electrodes of the first and second sub-pixels, and a light control unit in the transparent area, the light control unit being configured to block light incident from outside the display device in a first mode, and to transmit light incident from outside the display device in a second mode.

In the display device according to various embodiments of this disclosure, the light control unit can include a lower electrode, an upper electrode opposing the lower electrode, and a liquid crystal layer between the lower and upper electrodes.

In the display device according to various embodiments of this disclosure, the lower electrode and the upper electrode can be configured to flow no current therebetween in the first mode and to flow current therebetween in the second mode.

According to embodiments, switching between a virtual reality (VR) mode and an augmented reality (AR) mode can be enabled by forming transparent areas between sub-pixels and placing an optical control member over these transparent areas.

According to embodiments, the optical control member includes liquid crystal, an upper electrode on the liquid crystal, and a lower electrode beneath the liquid crystal, allowing the liquid crystal to be driven by the upper and lower electrodes to selectively block or transmit external light provided from below the display device.

To implement the AR mode, a high-resolution camera can be essential for capturing the external environment; however, this can cause discrepancies and delays between the external environment and the displayed screen, while also increasing costs due to the inclusion of the high-resolution camera. The embodiments implementing the AR mode by forming transparent areas and placing an optical control member over these areas to transmit external light are capable of reducing discrepancies and delays between the external environment and the displayed screen while lowering costs.

According to embodiments, the AR mode can be implemented without requiring a high-resolution camera, allowing for the simplification of material components.

However, the effects achievable through this disclosure are not limited to the aforementioned, and additional effects not explicitly described herein can be readily understood by those skilled in the art based on the disclosure.

Although the embodiments have been described with reference to the attached drawings, it will be understood by those skilled in the art that the described technical configurations can be implemented in other specific forms without altering the technical essence or essential features. Therefore, it should be understood that the embodiments described above are examples and not limited in all respects. Moreover, the scope of the embodiments is determined by the claims that follow, rather than by the detailed description. Any modifications or variations derived from the meaning, scope, and equivalent concepts of the patent claims are to be considered as falling within the scope of the embodiments.

### DESCRIPTION OF REFERENCE NUMERALS

1, 1_1, 1_2, 1_3, 1_4, 1_5: display device
2: substrate
3: insulating layer
41: anode electrode
5, 5_1, 5_2: common light-emitting layer
6: cathode electrode
7, 7_1: capping layer
8: encapsulation layer
9: color filter layer
BK: bank

What is claimed is:

1. A display device comprising:
a first sub-pixel, a second sub-pixel, and a transparent area between the first and second sub-pixels;
a substrate disposed across the first and second sub-pixels;
an anode electrode disposed on the substrate for each of the first and second sub-pixels;
a common light-emitting layer disposed on each of the anode electrodes of the first and second sub-pixels; and
a light control unit in the transparent area, the light control unit comprising a lower electrode, an upper electrode opposing the lower electrode, and a liquid crystal layer between the lower and upper electrodes.

2. The display device of claim 1, wherein the substrate is not disposed in the transparent area.

3. The display device of claim 2, further comprising a support part configured to support the light control unit in the transparent area.

4. The display device of claim 3, wherein the support part has an optical transmittance higher than an optical transmittance of the substrate.

5. The display device of claim 1, further comprising a bank disposed between the anode electrode and the common light-emitting layer, covering an end of the anode electrode.

6. The display device of claim 5, wherein the bank is not disposed in the transparent area.

7. The display device of claim 1, further comprising an insulating layer between the anode electrode and the substrate,
wherein the light control unit has a surface height lower than a surface height of the insulating layer.

8. The display device of claim 7, wherein the common light-emitting layer is not disposed in the transparent area.

9. The display device of claim 7, wherein the common light-emitting layer is separated from the transparent area.

10. The display device of claim 7, further comprising a cathode electrode on the common light-emitting layer,
wherein the first sub-pixel comprises a first reflective electrode within the insulating layer, and the second sub-pixel comprises a second reflective electrode within the insulating layer, and
wherein a distance between the first reflective electrode and the cathode electrode in the first sub-pixel is greater than a distance between the second reflective electrode and the cathode electrode in the second sub-pixel.

11. The display device of claim 10, wherein the cathode electrode is not disposed in the transparent area.

12. The display device of claim 10, further comprising an encapsulation layer on the cathode electrode,
wherein a thickness of the encapsulation layer in the transparent area is greater than a thickness of the encapsulation layer in the first sub-pixel.

13. A display device comprising:
a first sub-pixel, a second sub-pixel, and a transparent area between the first and second sub-pixels;
a substrate disposed across the first and second sub-pixels;
an anode electrode disposed on the substrate within each of the first and second sub-pixels;
a common light-emitting layer disposed on each of the anode electrodes of the first and second sub-pixels; and
a light control unit in the transparent area, the light control unit being configured to block external light incident on the display device in a first mode, and transmit external light incident on the display device in a second mode.

14. The display device of claim 13, wherein the light control unit comprises a lower electrode, an upper electrode opposing the lower electrode, and a liquid crystal layer between the lower and upper electrodes.

15. The display device of claim 14, wherein the lower electrode and the upper electrode are configured to flow no current therebetween in the first mode and flow current therebetween in the second mode.

16. The display device of claim 13, wherein the first mode is a virtual reality (VR) mode and the second mode is an augmented reality (AR) mode.
